(19) United States
(12) Patent Application Publication
(10) Pub. No.: US 2012/0009356 A1
(43) Pub. Date: Jan. 12, 2012

(54) CONTAMINATION REDUCING LINER FOR INDUCTIVELY COUPLED CHAMBER

(76) Inventors: Soo Young Choi, Fremont, CA (US); Qunhua Wang, San Jose, CA (US)

(21) Appl. No.: 13/238,729

(22) Filed: Sep. 21, 2011

Related U.S. Application Data
(63) Continuation of application No. 11/866,490, filed on Oct. 3, 2007.
(60) Provisional application No. 60/829,279, filed on Oct. 12, 2006.

(51) Int. Cl. C23C 16/505; H05H 1/24

(52) U.S. Cl. 427/579; 118/723 MP; 427/578

(57) ABSTRACT

A method and apparatus for depositing a film through a plasma enhance chemical vapor deposition process is provided. In one embodiment, an apparatus includes a processing chamber having a coil disposed in the chamber and routed proximate the chamber wall. A liner is disposed over the coil and is protected by a coating of a material, wherein the coating of material has a film property similar to the liner. In one embodiment, the liner is a silicon containing material and is protected by the coating of the material. Thus, in the event that some of the protective coating of material is inadvertently sputtered, the sputter material is not a source of contamination if deposited on the substrate along with the deposited deposition film on the substrate.

### CROSS-REFERENCE TO OTHER APPLICATIONS

This application is a continuation of co-pending U.S. patent application Ser. No. 11/866,490, filed Oct. 3, 2007, which claims benefit of U.S. Provisional Patent Application Ser. No. 60/829,279, filed Oct. 12, 2006, (Attorney Docket No. APPM/11572L). Each of the aforementioned patented applications is herein incorporated by reference.

### BACKGROUND OF THE INVENTION

1. Field of the Invention

Embodiments of the present invention generally relate to substrate processing apparatuses and methods, such as apparatuses and methods for flat panel display processing apparatuses (i.e. LCD, OLED, and other types of flat panel displays), semiconductor wafer processing, solar panel processing, and the like.

2. Description of the Related Art

Plasma enhanced chemical vapor deposition (PECVD) is generally employed to deposit thin films on a substrate such as a silicon or quartz wafer, large area glass or polymer workpiece, and the like. Plasma enhanced chemical vapor deposition is generally performed by introducing a precursor gas into a vacuum chamber that contains the substrate. The precursor gas is typically directed through a distribution plate situated near the top of the chamber. The precursor gas in the chamber is energized (e.g., excited) into a plasma by applying RF power to the chamber from one or more RF sources. The excited gas reacts to form a layer of material on a surface of the substrate that is positioned on a temperature controlled substrate support. In applications where the substrate receives a layer of low temperature polysilicon, the substrate support may be heated in excess of 400 degrees Celsius. Volatile by-products produced during the reaction are pumped from the chamber through an exhaust system. However, during plasma enhanced deposition processes, sputtering of chamber components may contaminate or otherwise result in poor quality of the deposited silicon film, thereby contributing to poor performance of the circuit or device.

Therefore, there is a need for an improved method and apparatus for depositing materials in a PECVD chamber.

### SUMMARY OF THE INVENTION

A method and apparatus for depositing silicon containing films in a PECVD chamber are provided. The method and apparatus is particularly suitable for use with large area glass or polymer substrate, such as those having a top surface area greater than 550 mm×650 mm.

In one embodiment, a plasma apparatus includes a processing chamber, a substrate support disposed in the processing chamber, a coil disposed in the processing chamber and circumscribing the substrate support, the coil is configured to inductively couple power to a plasma formed in the chamber, and a silicon containing liner disposed between the coil and substrate support, a surface of the liner facing the substrate support protected by a coating of material, wherein the coating of material has a film property similar to the silicon containing liner.

In another embodiment, a plasma apparatus includes a processing chamber, a substrate support disposed in the processing chamber, a coil disposed in the processing chamber and circumscribing the substrate support, the coil is configured to inductively couple power to a plasma formed in the chamber, a gas source having gases suitable for depositing a deposition film selected from at least one of a silicon containing gas in the processing chamber, and a quartz liner disposed over the coil, a face of the liner facing the substrate support having a coating of material which is similar in constitution to the deposition film on deposited a substrate.

In yet another embodiment, a method for depositing a film on a substrate by plasma enhance chemical vapor deposition may include disposing a substrate in a processing chamber having a coil extending around a substrate support assembly, wherein the coil is separated from the substrate support by a quartz liner protected by a first silicon containing material, wherein the first silicon containing material has a thickness greater than 10000 Å, providing a silicon containing gas into the chamber, applying power to the coil to inductively couple power to a plasma formed from the silicon containing gas, and depositing a second silicon containing film on the substrate.

In yet another embodiment, a plasma apparatus includes a showerhead, a substrate support disposed opposite the showerhead, a coil, a first power source coupled to the showerhead and the substrate support, a second power source coupled to the coil, and a silicon liner disposed over the coil.

### BRIEF DESCRIPTION OF THE DRAWINGS

So that the manner in which the above recited features of the present invention may be understood in detail, a more particular description of the invention, briefly summarized above, may be had by reference to embodiments, some of which are illustrated in the appended drawings.

FIG. 1A illustrates a schematic cross-sectional view of a plasma processing chamber that may be used in connection with one or more embodiments of the invention;

FIGS. 1B and 1C are cross-sectional views of an inductively coupled source assembly illustrated in FIG. 1A; and

FIG. 2 illustrates a top isometric view of a plasma processing chamber that may be used in connection with one or more embodiments of the invention.

To facilitate understanding, identical reference numerals have been used, wherever possible, to designate identical elements that are common to the figures. It is contemplated that features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Various embodiments of the invention are generally directed to an apparatus and method for reducing contamination in a processing chamber using an inductively coupled high density plasma. In general, various aspects of the present invention may be used for flat panel display processing, semiconductor processing, solar cell processing, or other substrate processing. The processing chamber includes a coil disposed in the chamber and routed proximate the chamber wall. A ceramic liner is disposed over the coil and is protected by a coating of a material, wherein the coating of material has a film property similar to the ceramic liner. Additionally, the coating of material also has a similar film property to a deposition film deposited on a substrate. Thus, in the event that some of the protective coating of material is inadvertently sputtered during plasma processing, the sputtered material will not become a source of contamination if deposited on the substrate along with the deposited deposition film.

Embodiments of the invention are illustratively described below with reference to a chemical vapor deposition system for processing large area substrates, such as a plasma enhanced chemical vapor deposition (PECVD) system, available from AKT, a division of Applied Materials, Inc., Santa Clara, Calif. However, it should be understood that the apparatus and method may have utility in other system configurations, including those systems configured to process round substrates.

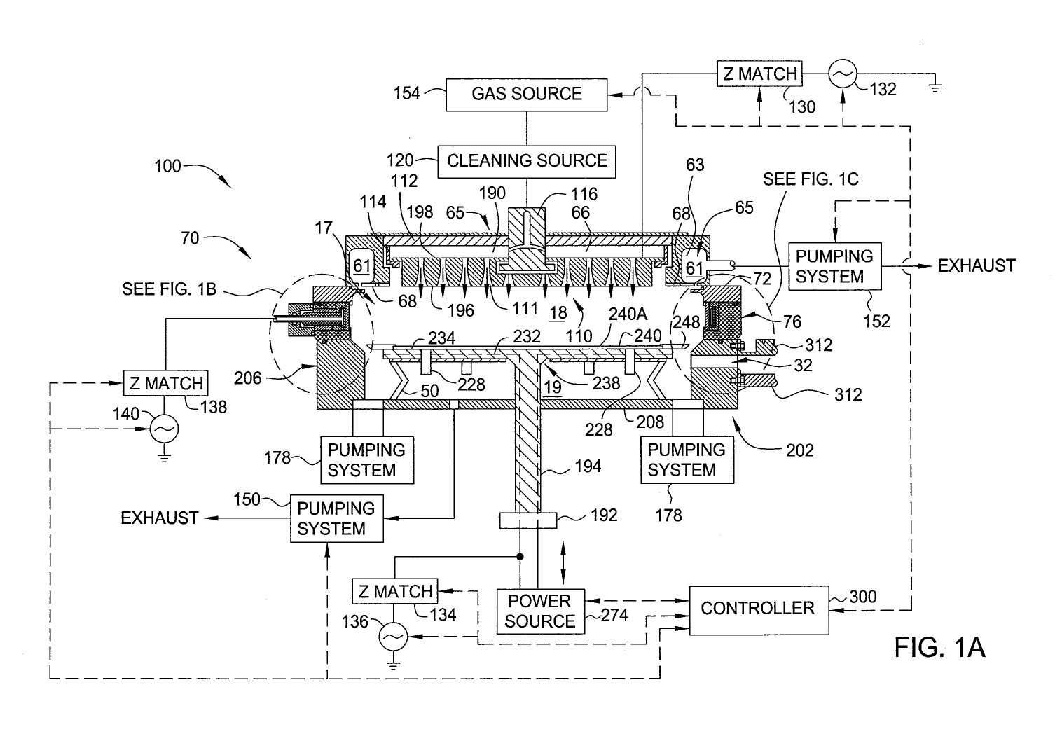

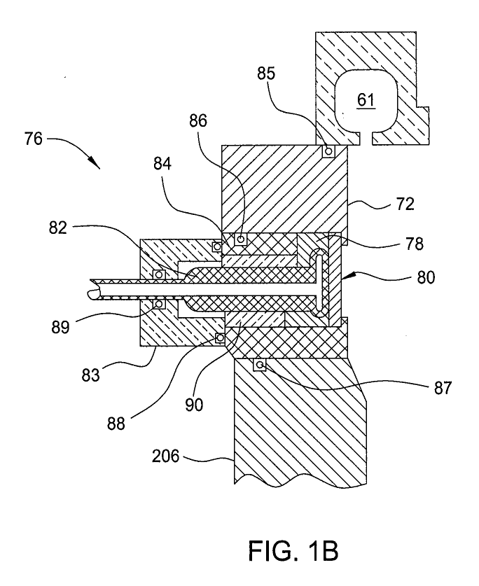

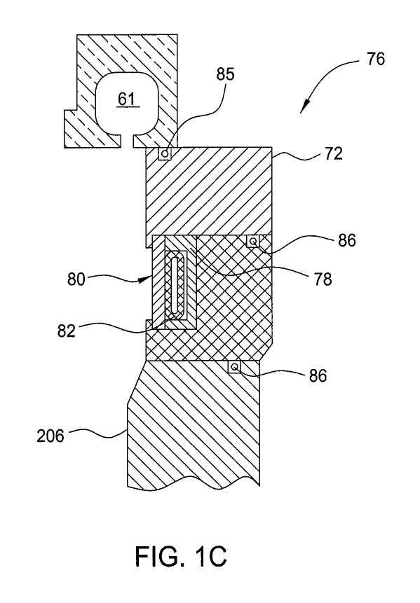

FIG. 1A illustrates a schematic cross-sectional view of a plasma processing chamber 100 that may be used in connection with one or more embodiments of the invention. The plasma processing chamber 100 include a chamber base 202 and a chamber lid 65 defining a chamber volume 17 within the processing chamber 100. The chamber base 202 includes walls 206 and a bottom 208. The chamber volume 17 includes an upper process volume 18 and a lower volume 19, which defines a region in which the plasma processing may occur. The lower volume 19 is partially defined by the chamber bottom 208 and the chamber walls 206. The upper process volume 18 is partially defined by the chamber lid 65, a lid support member 72 that supports the lid 65, and an inductively coupled source assembly 70 disposed between the lid support member 72 and the chamber base 202.

A substrate support assembly 238 is disposed in the chamber volume 17 of the processing chamber 100 and separates the volumes 18, 19. A stem 194 couples the support assembly 238 through the chamber base 202 to a lift system 192 which raises and lowers the substrate support assembly 238 between substrate transfer and processing positions.

A vacuum pump 150 is coupled to the processing chamber 100 to maintain the process volume 17 at a desired pressure. Optionally, one or more pumping system 178 may also be included in each side of the processing chamber 100. In one embodiment, turbo pumps may be used in the pumping system 178 to improve pumping conductance and low pressure control. In one embodiment, the processing chamber 100 includes two or more pumping ports disposed in the bottom 202 of the processing chamber 100 to connect to the pumping systems 150, 178. Each port is coupled to a separate vacuum pump, such as a turbo pump, rough pump, and/or Roots Blower™ pump, as required to achieve the desired chamber processing pressures, to improve pumping conductance and low pressure control.

A shadow frame 248 may be optionally placed over periphery of the substrate 240 when processing to prevent deposition on the edge of the substrate 240. Lift pins 228 are moveably disposed through the substrate support assembly 238 and are adapted to space the substrate 240 from the substrate receiving surface 234 to facilitate exchange of the substrate 240 with a robot blade through an access port 32. The access port 32 is defined in the chamber walls 206 included in the processing chamber base 202. The chamber walls 206 and chamber bottom 208 may be fabricated from a unitary block of aluminum or other material(s) compatible with processing. The substrate support assembly 238 may also include grounding straps 50 to provide RF grounding around the periphery of the substrate support assembly 238. Examples of grounding straps are disclosed in U.S. Pat. No. 6,024,044 issued on Feb. 15, 2000 to Law, et al. and U.S. patent application Ser. No. 11/613,934 filed on Dec. 20, 2006 to Park, et al., which are incorporated by reference in their entireties.

In one embodiment, the substrate support assembly 238 includes at least one embedded heater and/or cooling elements 232, such as a resistive heating element or fluid channels, in the substrate support assembly 238. In one embodiment, the embedded heater 232 is coupled to a power source 274, which may controllably heat the substrate support 238 and the substrate 240 positioned thereon to a predetermined temperature by use of a controller 300. Typically, in most CVD processes, the embedded heater 232 maintains the substrate 240 at a uniform temperature range below about 100° C. for plastic substrates. Alternatively, the embedded heater 232 may maintain the substrate 240 about above 400° C. for glass substrates.

A gas distribution plate 110 is coupled to a backing plate 112 disposed under the chamber lid 65 at its periphery by a suspension 114. The gas distribution plate 110 may also be coupled to the backing plate 112 by one or more center supports 116 to help prevent sag and/or control the straightness/curvature of the gas distribution plate 110. In one embodiment, the gas distribution plate 110 may be in different configurations with different dimensions. In an exemplary embodiment, the gas distribution plate 110 is a quadrilateral gas distribution plate. The gas distribution plate 110 has an upper surface 198 and a downstream surface 196 facing the substrate support assembly 238. The upper surface 198 faces a lower surface 196 of the backing plate 112. The gas distribution plate 110 includes a plurality of apertures 111 formed therethrough and facing the upper surface of the substrate 240 disposed on the substrate support assembly 238. The apertures 111 may have different shapes, numbers, profiles, densities, dimensions, and distributions across the gas distribution plate 110. A gas source 154 is coupled to the backing plate 112 to provide gas to a plenum 66 defined between the gas distribution plate 110 and the backing plate 112. The plenum 66 allows gases flowing into the plenum 66, 190 from the gas source 154 to distribute uniformly across the width of the gas distribution plate 110 and flow uniformly through the apertures 111. The gas distribution plate 110 is typically fabricated from aluminum (Al), anodized aluminum, or other RF conductive material. The gas distribution plate 110 is electrically isolated from the chamber lid 65 by an electrical insulation piece (not shown). In one embodiment, the gases that may be supplied from the gas source 154 include a silicon containing gas. Suitable examples of the silicon containing gas include SiH₄, TEOS, Si₂H₆ and the like. Other process gases, such as carrier gases or inert gases, may also be supplied into the processing chamber for processing. Suitable examples of carrier gases include N₂O, NH₃, N₂ and the like, and suitable examples of inert gases include He and Ar.

A cleaning source 120, such as an inductively coupled remote plasma source, may be coupled between the gas source 110 and the backing plate 112. The cleaning source 120 typically provides a cleaning agent, such as disassociated fluorine, to remove deposition by-products and stray deposited material left over after the completion of substrate processing. For example, between processing substrates, a cleaning gas may be energized in the cleaning source 120 to provide a remotely generated plasma utilized to clean chamber components. The cleaning gas may be further excited by the RF power provided to the gas distribution plate 110 by the power source 132. Suitable cleaning gases include, but are not limited to, NF₃, F₂, and SF₆. Examples of remote plasma sources are disclosed in U.S. Pat. No. 5,788,778 issued Aug. 4, 1998 to Shang, et al, which is incorporated by reference.

A RF power source 132 is coupled to the backing plate 112 and/or to the gas distribution plate 110 through RF impedance match element 130 to provide a RF power to create an electric field between the gas distribution plate 110 and the substrate support assembly 238 so that a plasma may be generated from the gases present in the process volume 18. Various RF frequencies may be used, such as a frequency between about 0.3 MHz and about 200 MHz. In one embodiment the RF power source is provided at a frequency of 13.56 MHz. Examples of gas distribution plates are disclosed in U.S. Pat. No. 6,477,980 issued on Nov. 12, 2002 to White et al., U.S. Publication No. 20050251990 published on Nov. 17, 2005 to Choi, et al., and U.S. Publication No. 2006/0060138 published on Mar. 23, 2006 to Keller, et al, which are all incorporated by reference in their entireties.

The chamber lid 65 include an upper pumping plenum 63 coupled to an external vacuum pumping system 152. The upper pumping plenum 63 may be utilized as an upper pumping port to uniformly evacuate the gases and processing by-products from the process volume 18. The upper pumping plenum 63 is generally formed within, or attached to, the chamber lid 65 and covered by a plate 68 to form the pumping channel 61. The lid support member 72 is disposed on the inductively coupled source assembly 70, which will be detail discussed with referenced to FIGS. 1B-C, may also be used to support the chamber lid 65. The vacuum pumping system 152 may include a vacuum pump, such as a turbo pump, rough pump, and/or Roots Blower™ pump, as required to achieve the desired chamber processing pressures.

Referring first to FIGS. 1B and 1C, the inductively coupled source assembly 70 includes an RF coil 82, a support structure 76, a liner 80, and various insulating pieces (e.g., an inner insulation 78, an outer insulation 90, etc.) The supporting structure 76 includes a supporting member 84 disposed below the lid support member 72. The supporting members 84 and the lid support member 72 are grounded metal parts that support the lid assembly 65. The RF coil 82 is supported and surrounded by a number of components which prevent the RF power delivered to the coil 82 from the RF power source 140 from arcing to the support structure 76 or incurring significant losses to the grounded chamber components (e.g., processing chamber base 202, etc.). The liner 80 is attached to the supporting structure 76. The liner 80 shields the RF coil 82 from interacting with the plasma deposition chemistries or from being bombarded by ions or neutrals generated during plasma processing or by chamber cleaning chemistries. Without the liner 80, aggressive ions and corrosive species generated during processing may attack the RF coil 82 and other portion of the chamber parts, resulting in the release of particles and the contamination into the processing chamber 100. By utilizing the liner 80 to shield and cover the RF coil 82 and adjacent portion of the chamber components, the RF coil 82 and chamber walls are effectively protected, thereby reducing potential process defects and contamination and increasing the lift of chamber parts.

In one embodiment, the liner 80 may be in form of a continuous annular ring, a band or an array of overlapping sections circumscribed by the RF coil 82 and preventing exposure of the coil 82 to the process volume 17. Optionally, the liner 80 may have an annular body formed and/or coated with a plasma and/or chemistry resistive material. The liner 80 may be made by a plasma and/or chemistry resistive material. In one embodiment, the liner 80 is fabricated from and/or coated with a ceramic material or other process-compatible dielectric material. Suitable examples of ceramic material include a silicon containing material, such as silicon oxide, silicon carbide, silicon nitride, or quartz, or other materials, such as aluminum nitride or aluminum oxide (Al₃O₂), and rare earth metal materials, such as yttrium or an oxide thereof. In one embodiment, the liner 80 may be fabricated from a material transmissive to the power applied to the coil disposed in the chamber, thereby allowing inductive coupling of the power to the plasma. One suitable example for this transmissive liner material is Al₃O₂. In another embodiment, the liner 80 is fabricated from and/or coated with a silicon containing material. One example of silicon containing material is quartz. In another embodiment, the material for the liner 80 is a material substantially similar to the material being deposited on the substrate, such that the material being deposited on the substrate is not contaminated. The liner 80 may have a thickness between about 0.1 inch and about 4 inch, such as about 0.25 inch and about 1.5 inch. In the embodiment wherein the processing chamber 100 may be in form of a quadrilateral configuration, the liner 80 may also be configured as a quadrilateral ring to circumscribe the RF coil 82 in the chamber walls. Alternatively, the liner 80 may be in form of any different configurations to meet different process requirements.

Also, various insulating pieces, for example, the inner insulation 78 and the outer insulation 90, may be used to support and isolate the RF coil 82 from the electrically grounded supporting structure 76. The insulating pieces are generally made from an electrically insulating materials, for example, TEFLON® polymer or ceramic materials. A vacuum feedthrough 83 is attached to the supporting structure 76 to hold and support the RF coil 82 while preventing atmospheric leakage into the upper process volume 18. The supporting structure 76, the vacuum feedthrough 83 and the various o-rings 85, 86, 87, 88 and 89 form a vacuum tight structure that supports the RF coil 82 and the gas distribution assembly 110, and allows the RF coil 82 to communicate with the upper process volume 18 with no conductive barriers that would inhibit the RF generated fields.

Referring back to FIG. 1A, the RF coil 82 is connected to the RF power source 140 through RF impedance match networks 138. In this embodiment, the RF coil 82 acts as an inductively coupled RF energy transmitting device that can generate and/or control the plasma present in the process volume 18. Dynamic impedance matching may be provided to the RF coil 82. By use of the controller 300, the RF coil 82, which is mounted at the periphery of the process volume 18, is able to control, position, and shape the plasma over the substrate surface 240A.

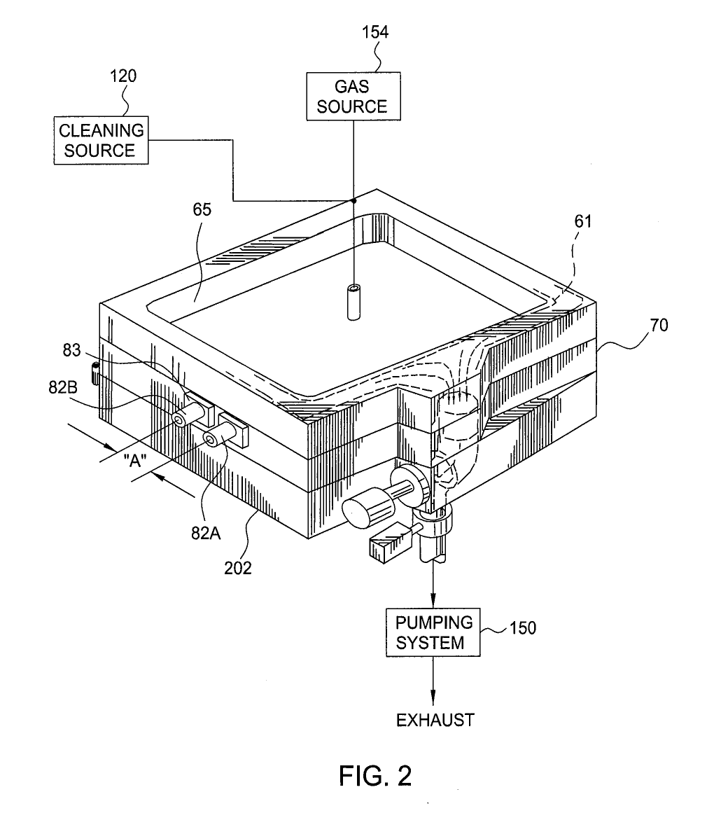

The RF coil 82 may be a single turn coil. As such, the coil 82 ends of a single turn coil may affect the uniformity of the plasma generated in the plasma processing chamber 100. When it is not practical or desired to overlap the ends of the coil, a gap region “A”, as shown in FIG. 2, may be left between the coil ends. The gap region “A,” due to the missing length of coil and RF voltage interaction at the input end 82A and output end 82B of the coil, may result in weaker RF generated magnetic field near the gap “A”. The weaker magnetic field in this region can have a negative effect on the plasma uniformity in the chamber. To resolve this possible problem, the reactance between the RF coil 82 and ground can be continuously or repeatedly tuned during processing by use of a variable inductor, which shifts or rotates the RF voltage distribution, and thus the generated plasma, along the RF coil 82, to time average any plasma non-uniformity and reduce the RF voltage interaction at the ends of the coil. An exemplary method of tuning the reactance between the RF coil 82 and ground, to shift the RF voltage distribution in a coil, is further described in the U.S. Pat. No. 6,254,738, entitled “Use of Variable Impedance Having Rotating Core to Control Coil Sputtering Distribution”, issued on Jul. 3, 2001, which is incorporated herein by reference. As a consequence, the plasma generated in the process volume 18 is more uniformly and axially symmetrically controlled, through time-averaging of the plasma distribution by varying the RF voltage distribution. The RF voltage distributions along the RF coil 82 can influence various properties of the plasma including the plasma density, RF potential profiles, and ion bombardment of the plasma-exposed surfaces including the substrate 240.

Referring back to FIG. 1A, the gas distribution plate 110 may be RF biased so that a plasma generated in the process volume 18 may be controlled and shaped by use of the impedance match element 130, the RF power source 132 and the controller 300. The RF biased gas distribution plate 68 acts as a capacitively coupled RF energy transmitting device that can generate and control the plasma in the process volume 18.

Further, an RF power source 136 may apply RF bias power to the substrate support 238 through an impedance match element 134. By use of the RF power source 136, the impedance match element 134 and the controller 300, the user can control the generated plasma in the process volume 18, control plasma bombardment of the substrate 240 and vary the plasma sheath thickness over the substrate surface 240A. The RF power source 136 and the impedance match element 134 may be replaced by one or more connections to ground (not shown) to ground the substrate support 238.

In operation, power can be independently supplied to the RF coil 82, gas distribution plate 110, and/or the substrate support 238 by use of the controller 300. By varying the RF power to the RF coil 82, the gas distribution plate 110 and/or the substrate support 238, the density of the plasma generated in the process volume 18 can be varied, since the plasma ion density is directly affected by the generated magnetic and/or electric field strength. The ion density of the plasma may also be increased or decreased through adjustment of the processing pressure or the RF power delivered to the RF coil 82 and/or the gas distribution plate 110.

After one or more substrates have been processed in the processing chamber 100, typically, a clean process is performed to remove the deposition by-products deposited and accumulated in the chamber walls. After the chamber walls has been sufficiently cleaned by the cleaning gases and the cleaning by-products have been exhausted out of the chamber, a seasoning process is performed in the process chamber. The seasoning process is performed to deposit a seasoning film onto components of the chamber to seal remaining contaminants therein and reduce the contamination that may generate or flake off from the chamber wall during process. The seasoning process comprises coating a material, such as the seasoning film, on the interior surfaces of the chamber in accordance with the subsequent deposition process recipe. In other words, the material of the seasoning film may be selected to have similar compositions, or film properties of the film subsequently deposited on the substrate. However, poor adhesion of conventional seasoning film to the chamber wall/chamber components often result in seasoning film peeling after a number of cycles of deposition and/or clean processes. Additionally, poor adhesion and incompatible film properties between the seasoning film, underlying chamber parts, and the deposition film incrementally accumulated on the seasoning film from the subsequent deposition process may become another source of contamination which may cause process defects during processing. Accordingly, it is believed that conventional techniques which deposit a thin layer of seasoning film, such as less than 5000 Å, is desired to provide good interface control of the seasoning film to the underlying chamber wall and the to-be-deposited deposition films. A seasoning film with higher thickness, such as greater than 5000 Å, is conventionally believed to have high likelihood of film peeling and poor adhesion to the underlying chamber parts, thereby increasing the source of contamination during processing.

In the embodiments described in the present invention, an enhanced seasoning film having a thickness greater than about 10,000 Å is enabled by using carefully selected similar underlying liner materials. The enhanced seasoning film has a high adhesion to the underlying chamber parts and the to-be-deposited deposition films. In an exemplary embodiment described herein, the enhanced seasoning film is a dielectric film that is applied to the chamber walls after performing film deposition and/or clean processes in the processing chamber 100. The enhanced seasoning film has a similar film composition to the underlying chamber parts (e.g., the liner 80) and the film deposited on the substrate, thereby eliminating contamination in the processing chamber 100. As described above, as the liner 80 is utilized to provide a barrier between the circumscribing at least a portion of the chamber wall and the RF coil 82 embedded in the chamber wall, the seasoning film is at least partially deposited on, or in contact with, the surface of the liner 80 facing the substrate support assembly 238. As the liner 80 is fabricated from a ceramic material, such as a silicon containing material, the seasoning film, e.g., a dielectric film, has a similar film property to the ceramic liner 80, thereby providing a good interface bonding therebetween. As the bonding interface between the seasoning film and the ceramic liner 80, e.g. the silicon containing liner, is enhanced, a greater thickness of the seasoning film may be utilized to better protect the chamber parts, RF coil 82, and other chamber hardware components, thereby efficiently reducing chamber contamination and process by-product defects. Moreover, as the underlying chamber components and RF coils 82 are now being protected by dual layers, e.g., the coated liner 80 and the enhanced seasoning film, the lifetime of the chamber parts and RF coil 82 is be increased as well, thereby reducing overall manufacturing cost and ensuring a better control of inductive plasma power generated through the RF coil 82.

In one embodiment, the seasoning film may be deposited on the chamber interior surface and on the liner 80 using gas mixtures identical to the gas mixtures used in the deposition processes performed in the chamber 100 after the seasoning process. The process parameters for coating the seasoning film may or may not be the same as the subsequent deposition process to meet different process requirements. During the seasoning process, a silicon precursor gas, an oxygen or a nitrogen containing gas and a carrier gas may be flown into the chamber 100 where the RF power source 132, 136, 140, provides radio frequency energy to activate the precursor gas and enables a season film deposition process. In an exemplary embodiment wherein the deposition process is configured to deposit a silicon oxide film, a gas mixture including at least a silicon precursor, an oxygen containing gas and an inert gas, such as argon or a helium gas, may be supplied to the chamber 100 for seasoning film deposition. Alternatively, in another exemplary embodiment wherein the deposition process is configured to deposition a silicon nitride film, a gas mixture including at least a silicon precursor, a nitrogen containing gas and an inert gas may be supplied to the chamber for seasoning film deposition.

In an exemplary embodiment, the silicon containing liner 80 is fabricated by quartz. In the embodiments wherein the silicon containing liner 80 is quartz, the subsequently seasoning film coated thereon is also configured to be a silicon containing film, thereby efficiently enhancing the adhesion between the quartz liner and the silicon containing film. Suitable examples of the silicon containing films include silicon oxide, silicon nitride, amorphous silicon, microcrystalline silicon, crystalline silicon, polysilicon, doped silicon films, and the like.

In one embodiment, the silicon precursor utilized for the seasoning process may have a flow rate between about 10 sccm and about 20,000 sccm. The oxygen or nitrogen containing gas has a flow rate between about 20 sccm and about 50,000 sccm. The inert gas has a flow rate between about 100 sccm and about 10,000 sccm. For example, in the embodiment wherein SiH₄ gas is used as the silicon precursor for film deposition, the ratio of the SiH₄ gas to the oxygen or nitrogen containing gas may be controlled between about 1:2 and about 1:5. In the embodiment wherein TEOS gas is used as the silicon precursor for film deposition, the ratio of the TEOS gas to the oxygen containing gas or nitrogen containing gas may be controlled between about 1:5 and about 1:20. A RF power between about 2,000 Watts and about 30,000 Watts may be supplied in the gas mixture. The RF power and gas flow rate may be adjusted to deposit the seasoning film with different silicon to oxide ratio, thereby providing a good adhesion to the subsequent to-be-deposited deposition film. Furthermore, the RF power and gas flow rate may be adjusted to control the deposition rate of the seasoning film, thereby efficiently depositing the seasoning film with a desired range of thickness to provide good protection and adhesion to the underlying liner 80, chamber parts and to-be-deposited. In one embodiment, the seasoning process may be performed for about 300 seconds to about 900 seconds while the deposition rate is maintained at between about 500 angstrom/minute to about 2000 angstrom/minute. In one embodiment, the seasoning film has a thickness greater than 10000 Å, such as about 15000 Å.

In some embodiments of the invention, the deposition process may be used to deposit silicon containing material using TEOS or other silicon precursor. The silicon containing layer may be at least one of amorphous silicon, microcrystalline silicon film (μc-Si), doped silicon, silicon oxide (SiOₓ) or silicon nitride, silicon oxynitride, amorphous carbon and silicon carbide. The seasoning film coated on the liner 80 and the chamber wall may be adjusted and varied in accordance with the deposition process subsequently performed to deposit the deposition film on the substrate. In one embodiment, the seasoning film may be made by the same material of the deposition film deposited on the substrate. In one embodiment, the seasoning film may be at least one of amorphous silicon, microcrystalline silicon film (μc-Si), doped silicon, silicon oxide (SiOₓ) or silicon nitride, silicon oxynitride, amorphous carbon and silicon carbide. In the embodiment wherein the seasoning film is selected to be the same as the deposition film deposited on the substrate, the similar film properties of the seasoning film and deposition film coated thereon promotes the adhesion and interfacial bonding therebetween. Additionally, in the event that some of the seasoning film is inadvertently sputtered attacked by plasma, the sputtered or flaked material is not a source of contamination if deposited on the substrate along with the deposited deposition film as the seasoning film and the deposition film have similar film properties. Therefore, by controlling the compatibility of the film properties among the liner 80, seasoning film and the deposition film, contamination and particle defect sources may be efficiently controlled.

In some embodiments of the invention, the deposition process may be used to form a high quality gate dielectric layer using various processes, including a high density plasma oxidation (HDPO) process. Other details of the HDPO process may be described in commonly assigned U.S. patent application Ser. No. 10/990,185, filed Nov. 16, 2004, under the title “Multi-Layer High Quality Gate Dielectric For Low-Temperature Poly-Silicon TFTs”, which is incorporated herein by reference.

Thus, an apparatus for plasma enhance chemical vapor depositing a dielectric film on a substrate with efficient contamination control is provided. By utilizing a ceramic liner covering a RF coil in combination with an enhanced seasoning film, a good chamber interior surface protection and low chamber contamination is obtained. The apparatus advantageously provides a good manner for protecting RF coils and chamber parts disposed in a processing chamber from plasma attack during processing, thereby efficiently reducing process defects and chamber contamination.

While the foregoing is directed to embodiments of the present invention, other and further embodiments of the invention may be devised without departing from the basic scope thereof, and the scope thereof is determined by the claims that follow.

What is claimed is:

1. A plasma apparatus, comprising:
a processing chamber;
a substrate support disposed in the processing chamber;
a gas distribution plate disposed over the substrate support;
a first RF power source coupled between the substrate support and gas distribution plate for forming a plasma therebetween;
a coil disposed in the processing chamber and circumscribing the substrate support;
a second RF power source coupled to the coil, wherein the coil is configured to inductively couple power to a plasma formed between the gas distribution plate and the substrate support;
a liner formed from a silicon containing material disposed between the coil and substrate support; and
a coating formed on a surface of the liner facing the substrate support for protecting the surface of the liner, wherein the coating comprises a material having properties similar to the silicon containing material of the liner.

2. The apparatus of claim 1, wherein the coating comprises a seasoning material.

3. The apparatus of claim 2, wherein the seasoning material is a silicon containing material.

4. The apparatus of claim 1, wherein the liner coating has a thickness greater than about 10000 Å.

5. The apparatus of claim 4, wherein the liner coating of the material has a thickness about 15000 Å.

6. The apparatus of claim of claim 1, wherein the coating is at least one of amorphous silicon, microcrystalline silicon film (μc-Si), doped silicon, silicon oxide (SiOₓ) or silicon nitride, silicon oxynitride, amorphous carbon and silicon carbide.

7. The apparatus of claim 6, wherein the coating comprises silicon oxide (SiOₓ) or silicon nitride.

8. The apparatus of claim 1, wherein the silicon containing liner is quartz.

9. A plasma apparatus, comprising:
a processing chamber;
a substrate support disposed in the processing chamber;
a gas distribution plate disposed over the substrate support;
a first RF power source coupled between the substrate support and gas distribution plate for forming a plasma in the processing chamber;
a coil disposed in the processing chamber and circumscribing the substrate support, wherein the coil is configured to inductively couple power to a plasma formed in the processing chamber;
a gas source having gases suitable for depositing a deposition film selected from at least one of a silicon containing gas in the processing chamber;
a quartz liner disposed over the coil, wherein the quartz liner comprises a coating of material on a surface facing the substrate support, and the coating of material is similar in constitution to the deposition film on deposited a substrate.

10. The method of claim 9, wherein the silicon containing gas is at least one of SiH₄, TEOS and Si₂H₆.

11. The apparatus of claim 9, wherein the coating of material is a silicon containing material selected from at least one of amorphous silicon, microcrystalline silicon film (μc-Si), doped silicon, silicon oxide (SiOₓ) or silicon nitride, silicon oxynitride, amorphous carbon and silicon carbide.

12. The apparatus of claim 9, wherein the deposition film deposited on the substrate is at least one of amorphous silicon, microcrystalline silicon film (μc-Si), doped silicon, silicon oxide (SiOₓ) or silicon nitride, silicon oxynitride, amorphous carbon and silicon carbide.

13. The apparatus of claim 9, wherein the coating of material and the deposition film are fabricated from the same material.

14. The apparatus of claim 9, wherein the coating of material has a thickness greater than about 10000 Å.

15. The apparatus of claim 9, wherein the coating of material comprises silicon oxide (SiOₓ) or silicon nitride.

16. A method for depositing a film on a substrate by plasma enhanced chemical vapor deposition, comprising:
disposing a substrate on a substrate support in a processing chamber;
providing a silicon containing gas into the chamber through a showerhead disposed over the substrate support;
forming a plasma from the silicon containing gas by applying a first RF power between the substrate support and the showerhead;
applying a second RF power to a coil extending around a substrate support assembly, wherein the coil inductively couples power to the plasma formed from the silicon containing gas, a quartz liner is disposed between the coil and the substrate support, the quartz liner has a coating comprising a first silicon containing film; and
depositing a second silicon containing film on the substrate.

17. The method of claim 16, wherein the first and the second silicon containing film are at least one of amorphous silicon, microcrystalline silicon film (μc-Si), doped silicon, silicon oxide (SiOₓ) or silicon nitride, silicon oxynitride, amorphous carbon and silicon carbide.

18. The method of claim 16, wherein depositing the second silicon containing film on the substrate further comprises:
depositing the second silicon containing film on the first silicon containing material while depositing on the substrate.

19. The method of claim 16, wherein the first and the second silicon containing material are the same material.

20. The method of claim 16, wherein the first silicon containing material is coated on a portion of the quartz liner facing the substrate support assembly.
